(19) United States
(12) Patent Application Publication
(10) Pub. No.: US 2012/0139638 A1
(43) Pub. Date: Jun. 7, 2012

(54) Methods and Circuits for Controlling Amplifier Gain Over Process, Voltage, and Temperature

(75) Inventors: Kambiz Kaviani, Palo Alto, CA (US); Amir Amirkhany, Sunnyvale, CA (US); Aliazam Abbasfar, Campbell, CA (US)

(73) Assignee: Rambus Inc., Sunnyvale, CA (US)

(21) Appl. No.: 13/310,609

(22) Filed: Dec. 2, 2011

Related U.S. Application Data
(60) Provisional application No. 61/419,406, filed on Dec. 3, 2010.

(51) Int. Cl. H03F 3/04

(52) U.S. Cl. 330/289

(57) ABSTRACT

A receiver includes an amplifier and a transconductance bias circuit. The amplifier gain is largely determined by transconductance and load impedance. The transconductance bias circuit varies the transconductance in inverse proportion to the load impedance to maintain the gain over process, voltage, and temperature. Differential amplifiers can use separate transconductance bias circuits for each amplifier leg, and the bias circuits can be independently controlled to minimize common-mode gain and voltage offsets.

### TECHNICAL FIELD

The subject matter presented herein relates generally to electronic amplifiers, and more particularly to methods and circuits for controlling gain and signal offsets.

### BACKGROUND

An electronic amplifier is a device for increasing the power of a signal. The power increase is a consequence of some form of “gain,” a multiplication factor relating the magnitude of the amplifier's output to its input signal. An amplifier's gain may be specified as the ratio of output voltage to input voltage (voltage gain), output current to input current (current gain), or output power to input power (power gain).

High-speed amplifiers are commonly formed on integrated circuits (IC) using photolithographic and chemical processes. Despite attempts to ensure uniformity, process variations result in physical and chemical differences within and between integrated circuits. Such process variations lead to undesirable variations in amplifier gain. Process and other variations also impact supply voltages, which likewise affect amplifier gain. Temperature can also have a profound effect. Process mismatches can also introduce signal “offsets,” in which case a differential amplifier can provide different responses for complementary but otherwise identical signals.

Gain variations and offsets that result from process, voltage, and temperature (PVT) variations can introduce errors and reduce speed performance, particularly for high-performance, low-power amplifiers. Sensitive amplifiers may therefore require some form of manual or automated tuning. The circuits and techniques required for such tuning can be complex, area-intensive, and time consuming. There is therefore a need for simple and inexpensive methods and circuits for calibrating and maintaining amplifier gain and signal offsets across process, voltage, and temperature.

### BRIEF DESCRIPTION OF THE FIGURES

The subject matter disclosed is illustrated by way of example, and not by way of limitation, in the figures of the accompanying drawings and in which like reference numerals refer to similar elements and in which:

FIG. 1 depicts an integrated circuit 100 that includes a receiver 105 in accordance with one embodiment;

FIG. 2 depicts an integrated circuit 200 that includes a receiver 205 in accordance with an embodiment that uses a common-gate amplifier configuration to enable high data rates at relatively low signaling power.

FIG. 3 depicts a differential receiver 300 in accordance with an embodiment that controls gain over process, voltage, and temperature as discussed previously, and further supports calibration methods that can be used to reduce or eliminate offsets and common-mode gain.

FIG. 4 depicts a differential receiver 400 in accordance with another embodiment that controls gain, supports offset cancellation, and that can be used to reduce or eliminate undesirable common-mode gain.

### DETAILED DESCRIPTION

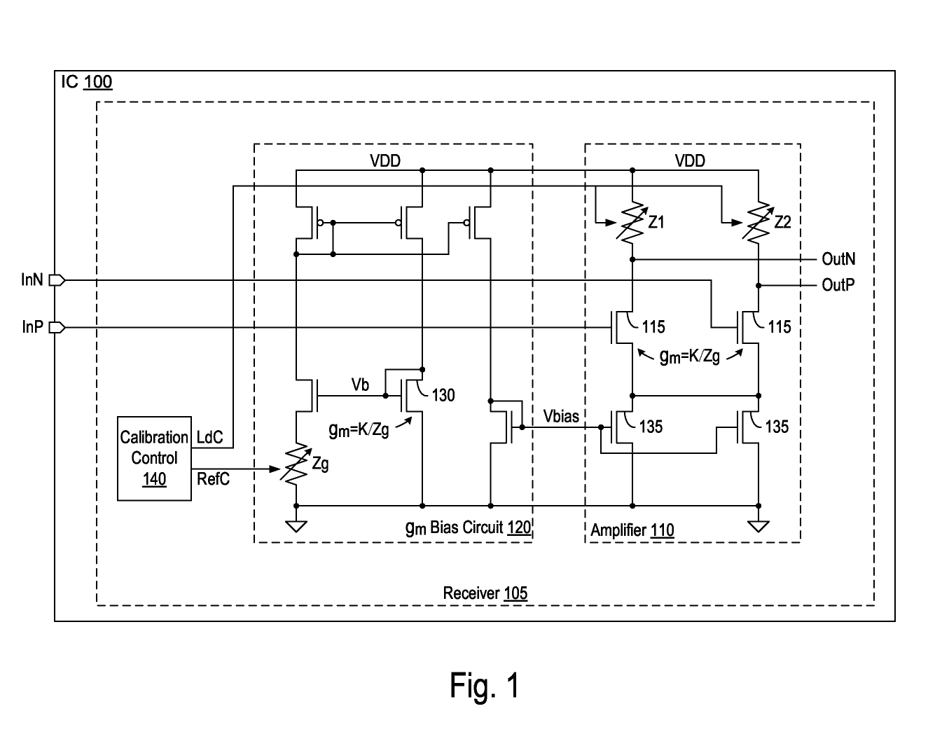

FIG. 1 depicts an integrated circuit 100 that includes a receiver 105 in accordance with one embodiment. Receiver 105 includes a differential amplifier 110, the absolute gain of which is largely determined by the transconductances gₘ of a matched pair of transistors 115 and their respective load impedances Z1 and Z2. A transconductance bias circuit 120 issues a bias control signal Vbias to amplifier 110 that controls transconductance gₘ of transistors 115. This control, based on the PVT response of a reference impedance Zg, precisely tracks a similar PVT response of load impedances Z1 and Z2 such that the gain of amplifier 110 remains relatively constant across process, voltage, and temperature.

The transconductance gₘ of a transistor is the ratio of the current change at the output node to the voltage change at the input node. Bias circuit 120 develops a bias voltage Vb to set the transconductance gₘ of transistors 130 at a value K/Zg, where K is a fixed design parameter of bias circuit 120 and Zg is the impedance of a like-designated resistor. Bias circuit 120 replicates bias voltage Vb as a second bias voltage Vbias, which is shared with a pair of transistors 135 in amplifier 110 to control the currents through transistors 115. These currents fix the transconductance gₘ of transistors 115 equal to that of transistor 130.

Transconductance gₘ is controlled by a reference impedance Zg that varies with process, voltage, and temperature. To accommodate process variations, reference impedance Zg can be adjusted to a desired impedance by application of a digital or analog reference-control signal RefC from calibration control circuit 140. Impedance, in this context, is a measure of opposition to current flow, and has resistive, inductive and capacitive components. The inductive and capacitive components are disregarded in this example because the resistive component dominates. Inductive or capacitive components may be adjustable in other embodiments.

To a first approximation, the value of reference impedance Zg varies with temperature T according to the following equation 1, where Zg₀ is the value of impedance Zg at a temperature Tₒ, and α is a temperature coefficient for the resistor:

Zg=Zg₀(α(T−T₀)+1) (1)

The value of transconductance gₘ for transistors 130 and 115 is constant K divided by impedance Zg (gₘ=K/Zg). Because impedance Zg varies with temperature, so too does transconductance gₘ. Stated mathematically:

gₘ=K/(Zg₀(α(T−T₀)+1)) (2)

The voltage gain Av of each leg of amplifier 110 is the product of the transconductance gₘ and the respective load impedance. That is, the gains provided by the left and right legs are gₘZ1 and gₘZ2, respectively. Reference impedance Zg is a replica of load impedances Z1 and Z2, so the α coefficients are the same or nearly so. The load and replica impedances thus exhibit similar temperature responses. Namely, the values of impedances Z1 and Z2 vary with temperature T according to the following equations 3 and 4, which are similar to equation 1:

Z1=Z1₀(α(T−T₀)+1) (3)

Z2=Z2₀(α(T−T₀)+1) (4)

As noted previously, the absolute gain of each leg of amplifier 110 equals the product of transconductance gₘ and the respective load impedance, and the load impedance tracks reference impedance Zg. The absolute gain A_{VL} of the left-hand leg of amplifier 110 can therefore be expressed as:

A_{VL}=gₘZ1=gₘZ1₀(α(T−Tₒ)+1) (5)

Substituting for gₘ using equation 2 gives:

A_{VL}(K/(Zg₀(α(T−T₀)+1))(Z1₀(α(T−T₀)+1)) (6)

which simplifies to:

A_{VL}=K(Z1₀/Zg₀) (7)

Applying the same steps, the gain A_{VR} of the right-hand leg of amplifier 110 simplifies to:

A_{VR}=K(Z2₀/Zg₀) (8)

Both legs of amplifier 110 thus exhibit a temperature-independent gain proportional to the ratio of their respective load impedance to the reference impedance at temperature T₀.

Load impedances Z1 and Z2 are equal in the embodiment of FIG. 1, and their values are controlled by a common load-control signal LdC from calibration control circuit 140. Calibration control circuit 140 likewise controls reference impedance Zg using a reference-control signal RefC. The two control signals can be adjusted independently to adjust the impedance ratios of equations 7 and 8, and thus the gain of amplifier 110. Once the impedances are thus calibrated, the gain of amplifier 110 remains relatively constant despite temperature changes that impact the reference and load impedances. Relatively simple and inexpensive control mechanisms are thus able to precisely calibrate amplifier gain, and to control that gain over process, voltage, and temperature.

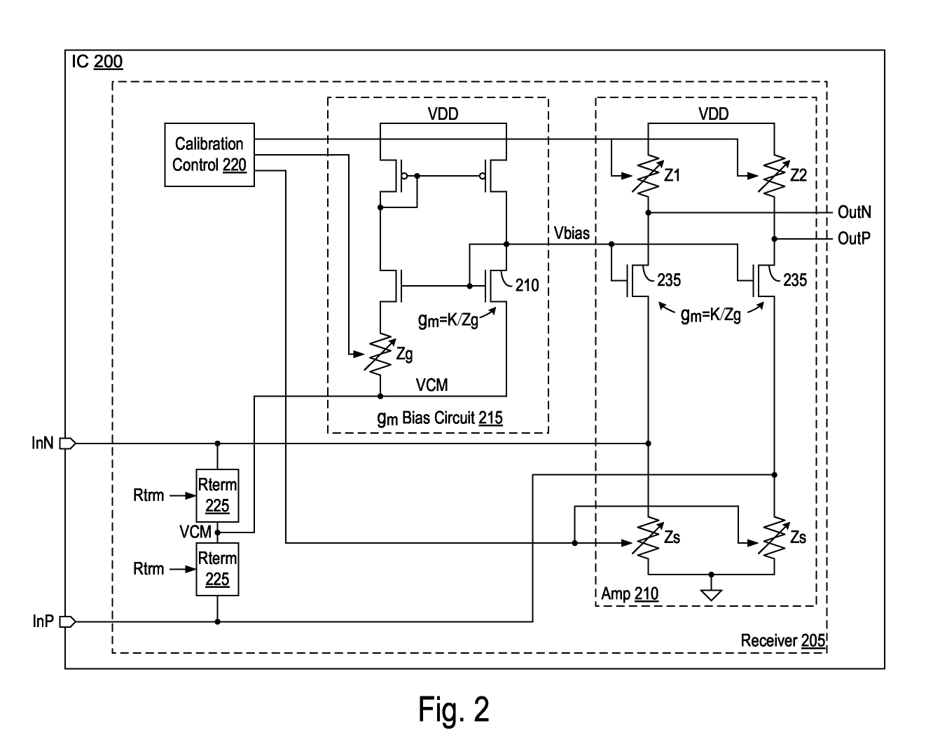

FIG. 2 depicts an integrated circuit 200 that includes a receiver 205 in accordance with an embodiment that uses a common-gate amplifier configuration to enable high data rates at relatively low signaling power. As in the previous example, receiver 205 includes a differential amplifier 210 that exhibits a constant gain over a range of temperatures as a consequence of compensation provided by a transconductance bias circuit 215. A calibration control circuit 220 can be used to calibrate the transconductance and gain of amplifier 210.

IC 200 includes input nodes InN and InP, which are terminated to a common-mode voltage node VCM via respective termination elements 225. Termination elements are optionally adjustable over a range of termination impedances responsive to a control signal Rtrm. Though not shown, IC 200 may additionally include termination control circuitry to determine the value of control signal Rtrm. This determination may be based upon an external reference resistor, on integrated replica termination element, or both.

Amplifier 210 may be a receiver input stage that supports near-ground differential signaling. Amplifier 210 level shifts the incoming signal InN/InP using a differential pair of transistors 235. The control terminals of transistors 235 are coupled to a bias voltage Vbias, and each transistor 235 includes a first current-handling terminal coupled to a supply node VDD via a respective load impedance and a second current-handling terminal coupled to a second supply node (ground) via a source impedance Zs. Transistors 235 are NMOS transistors in a common-gate configuration in this example, but may be other types of transistors and otherwise configured in other embodiments.

The gain of each leg of amplifier 210 is the product of the transconductance gₘ of the respective transistor and the load impedance. Bias circuit 215, by deriving bias voltage Vbias, sets the transconductances gₘ of transistors 235 as detailed above in connection with FIG. 1. Also similar to that prior example, the load impedances Z1 and Z2 are replicas of reference impedance Zg, and so vary in the same manner over process, voltage, and temperature. These temperature coefficients cancel to leave the gain of amplifier 210 relatively constant over temperature.

Amplifier 210 is a differential amplifier, and receives a differential input signal on nodes InP and InN. The common-mode voltage VCM used as a reference for bias circuit 215 need not be provided by a separate reference-voltage source, but can instead be derived from the incoming signal. In such embodiments both bias circuit 215 and amplifier 210 can automatically adapt to changes in the common-mode voltage of the input signal. The common-mode voltage VCM can be provided by a reference within or external to IC 200 in other embodiments. Furthermore, embodiments that support single-ended signaling can sense a mid-point of the input signal excursion for use as a reference, or can use a separate internal or externally supplied reference.

Control circuitry 220 communicates control signals to load impedances Z1 and Z2, source impedances Zs, and reference impedance Zg. These control signals can be calibrated to set a desired gain for amplifier 210. Control circuitry 220 may include or be coupled to a register, for example, that stores a calibration value selected to e.g. account for process variations.

The calibrated gain of the amplifiers of FIGS. 1 and 2 remains relatively constant over temperature and voltage due to the countervailing actions of the bias circuit 215 and the load impedances. The ability to maintain a constant gain is advantageous, but other qualities are also important for effective high-speed, low-power communication channels. For differential amplifiers, these qualities include the ability to amplify the difference between complementary signal components while rejecting signals common to both. Stated differently, a differential amplifier ideally exhibits high differential gain and low “common-mode” gain. A related issue, “offsets,” refers to the possibility that a differential amplifier may provide different responses for the two complementary components. Such imbalances can occur due to e.g. process mismatches, and can introduce receive errors.

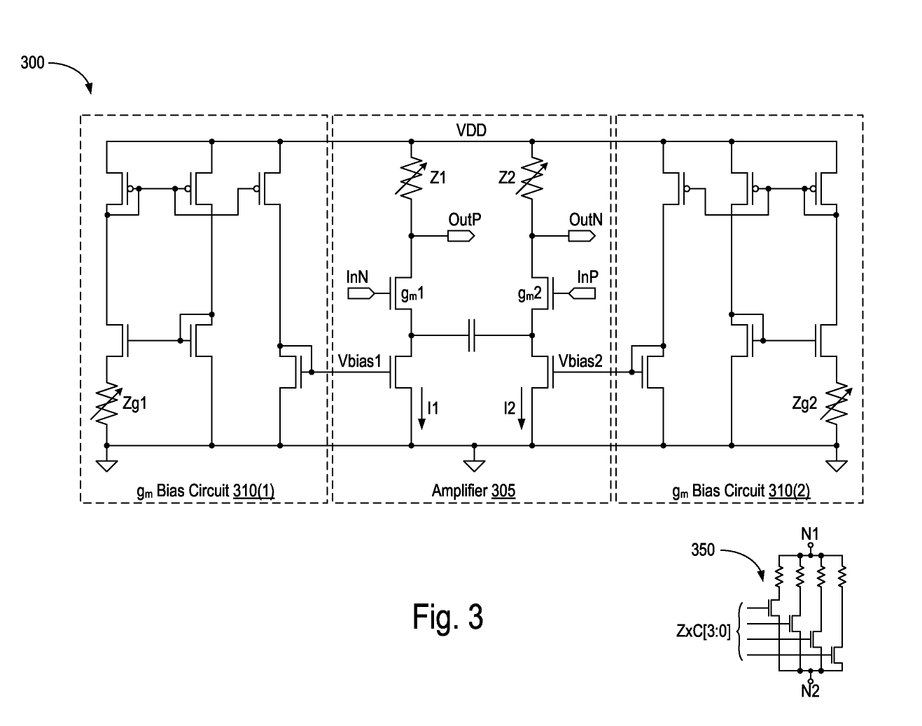

FIG. 3 depicts a differential receiver 300 in accordance with an embodiment that controls gain over process, voltage, and temperature as discussed previously, and further supports calibration methods that can be used to reduce or eliminate offsets and common-mode gain.

Receiver 300 includes a differential amplifier 305, including two legs that pass respective bias currents I1 and I2. Bias currents I1 and I2 are set by respective bias voltages Vbias1 and Vbias2 from a pair of complementary transconductance-bias circuits 310(1) and 310(2). Reference impedances Zg1 and Zg2 in bias circuits 310(1) and 310(2) can separately control input transconductances gₘ1 and gₘ2 of amplifier 305, and consequently the gain provided by each of the two legs of amplifier 305.

Reference impedances Zg1 and Zg2 can be controlled by separate digital or analog control circuits (not shown), all or part of which may be instantiated within receiver 300 or elsewhere. If the load impedances and transconductances are matched, the gains of the two amplifier legs are equal (gₘ1*Z1=gₘ2*Z2) and the common mode gain Avcm is zero (Avcm=gₘ1*Z1−gₘ2*Z2). Mismatches between the amplifier legs or associated input and output signal paths can alter the gain of one or both legs, and consequently produce a non-zero common-mode gain. Such mismatches can be calibrated away by adjustment of reference impedances Zg1 and Zg2, load impedances Z1 and Z2, or a combination of the reference and load impedances.

To calibrate receiver 300 in accordance with one embodiment, input nodes InN and InP are both set to a DC common-mode voltage. The voltages on output nodes OutP and OutN are then set equal by adjusting the reference impedances, load impedances, or both until the product of current I1 and load impedance Z1 equals the products of current I2 and load impedance Z2. Expressed mathematically:

Z1*I1=Z2*I2 (9)

Dividing both sides by Z2*I1 gives:

Z1/Z2=I2/I1 (10)

For semiconductor processing technologies considered to be advanced at the time of this writing, the ratio of currents I2 and I1 essentially equals the ratio of transconductances gₘ2 and gₘ1. Expressed mathematically:

gₘ2/gₘ1=I2/I1 (11)

Combining equations 10 and 11 gives:

gₘ₂/gₘ1=Z1/Z2 (12)

Finally, cross multiplying equation 12 gives:

gₘ2*Z2=gₘ1*Z1 (13)

As discussed previously, the gain of each amplifier leg is the product of transconductance and the respective load impedance. That is, the gain provided by the left and rights legs are gₘ*Z₁ and gₘ*Z₂, respectively. Per equation 13, calibrating amplifier 305 for zero offset equalizes the gain of the two legs, and thus sets the common-mode gain to zero (Avcm=0).

Reference impedances Zg1 and Zg2 are replicas of load impedances Z1 and Z2, respectively, and so behave similarly across process, voltage, and temperature. Bias circuits 310(1) and 310(2) adjust transconductances gₘ1 and gₘ2 responsive to temperature in inverse proportion to the changes in load impedances Z1 and Z2. The gains of the legs of amplifier 305 therefore remain relatively constant. Receiver 300 therefore provides a low DC offset and common-mode gain while supporting a constant differential gain. Relatively simple and efficient control circuitry thus eliminates the need for periodic offset and gain calibration.

A simple embodiment of a variable impedance 350 suitable for use as adjustable reference and load impedances is shown in the lower right of FIG. 3. Similar structures may be used for integrated termination impedances. The resistance between two nodes N1 and N2 is selected by application of an impedance control signal ZxC[3:0] that enables one or a combination of four transistors to place one or more resistors in parallel between the nodes. The values of the resistor may be e.g. binary weighted, and the number of resistive settings may be more or fewer. Analog or a combination of analog and digital control signals might also be used in other embodiments. Impedance 350 is a simple representation of a well-known class of impedance elements that can be modified by application of digital or analog control signals, many variants of which are well known to those of skill in the art.

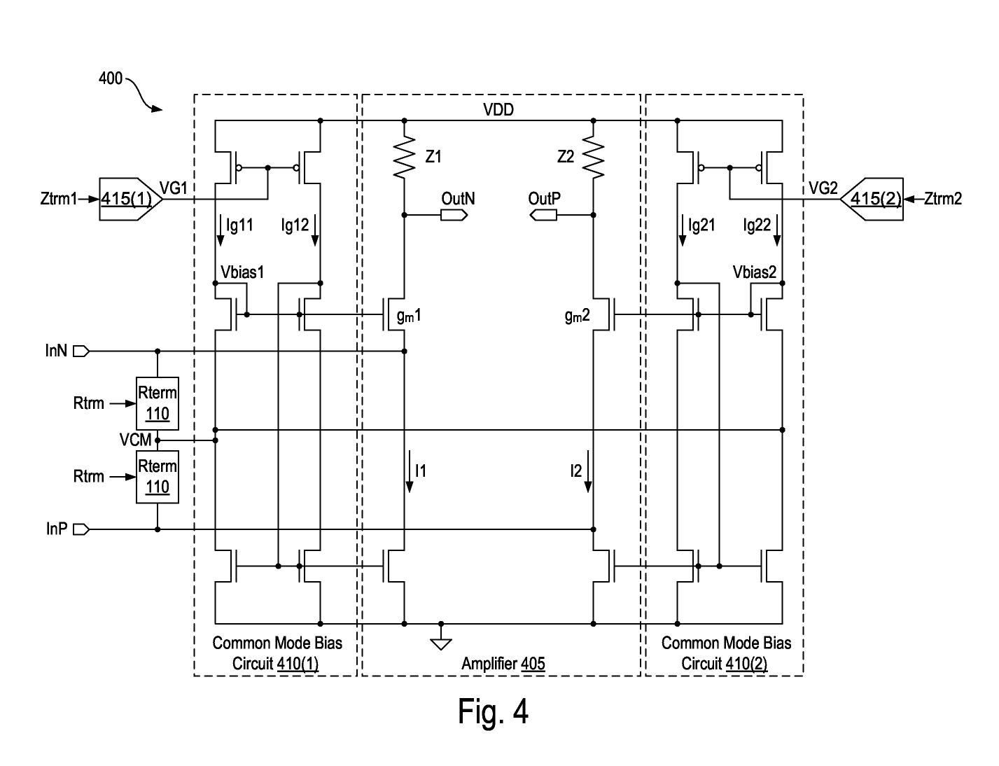

FIG. 4 depicts a differential receiver 400 in accordance with another embodiment that controls gain, supports offset cancellation, and that can be used to reduce or eliminate common-mode gain.

Receiver 400 includes a common-gate differential amplifier 405, including two legs that pass respective bias currents I1 and I2. Bias currents I1 and I2 are set by respective bias voltages Vbias1 and Vbias2 from a pair of complementary transconductance-bias circuits 410(1) and 410(2). Reference currents Ig11, Ig12, Ig21 and Ig22 in bias circuits 410(1) and 410(2) can separately control input transconductances gₘ1 and gₘ2 of amplifier 405, and consequently the gain provided by each of the two legs.

Reference currents Ig11, Ig12, Ig21 and Ig22 can be controlled by separate digital-to-analog converters (DACs) 415(1) and 415(2), which convert digital control signals Ztrm1 and Ztrm2 into respective analog voltages VG1 and VG2. The analog voltages control the currents Ig11, Ig12, Ig21, and Ig22 of respective pairs of PMOS transistors in bias circuits 410(1) and 410(2), which in turn establish bias voltages Vbias1 and Vbias2. These bias voltages determine transconductances gₘ₁ and gₘ₂ of amplifier 405 in the manner described above in connection with other embodiments. Analog voltages VG1 and VG2 can be generated from transconductances gm1 and gm2 using gm bias circuits similar to circuit 215 of FIG. 2.

Mismatches between the amplifier legs or associated input and output signal paths can be calibrated away by careful adjustment of reference currents Ig11, Ig12, Ig21, and Ig22. Load impedances Z1 and Z2 are not adjustable in this example, but may be in other embodiments. Offset voltages and common-mode gain can be calibrated as discussed above. Briefly, input nodes InN and InP are both set to common-mode voltage VCM and the voltages on output nodes OutP and OutN are equalized by adjusting the currents Ig11, Ig12, Ig21, and Ig22. These reference currents are provided by PMOS transistors in this example, and may be adjusted by controlling their gate voltages. Load impedances Z1 and Z2 can be implemented in the same way.

Various coding schemes can be used to present data on input nodes InN and InP. So long as these are balanced, common-mode voltage VCM will remain relatively constant without connection to a reference. The common-mode voltage VCM can therefore be derived from the incoming signal, rather than from some voltage reference. Deriving the common-mode voltage from the incoming signal or signals eliminates the requirement of a separate reference and allows the bias circuits and amplifier to automatically adapt to changes in the input signal. The common mode biasing circuits 410(1) and 410(2) in FIG. 4 enable such adaptation while reducing or eliminating offset and common-mode-gain errors. In one embodiment voltage VCM is approximately zero volts, and each signal is less than one volt peak-to-peak.

While the present invention has been described in connection with specific embodiments, variations of these embodiments are also contemplated. Still other variations will be obvious to those of ordinary skill in the art. Moreover, some components are shown directly connected to one another while others are shown connected via intermediate components. In each instance the method of interconnection, or “coupling,” establishes some desired electrical communication. Such coupling may often be accomplished in many ways using various types of intermediate components and circuits, as will be understood by those of skill in the art. Therefore, the spirit and scope of the appended claims should not be limited to the foregoing description. For U.S. applications, only those claims specifically reciting “means for” or “step for” should be construed in the manner required under the sixth paragraph of 35 U.S.C. §112.

What is claimed is:

1. An integrated circuit comprising:
an amplifier including a transistor having first and second current-handling terminals coupled in series with a load, the transistor exhibiting a transconductance and the load a load impedance that vary with temperature; and
a variable-transconductance-bias circuit coupled to the transistor to vary the transconductance with the temperature, the transconductance-bias circuit having a reference element exhibiting a reference impedance that varies with the temperature and is a function of the load impedance.

2. The integrated circuit of claim 1, wherein the transistor is connected in a common-source configuration.

3. The integrated circuit of claim 1, wherein at least one of the load and the reference element includes a control port to set the respective impedance.

4. The integrated circuit of claim 3, further comprising a calibration control circuit coupled to the control port to issue a control signal.

5. The integrated circuit of claim 4, wherein the control signal adjusts a ratio of the load impedance to the reference impedance.

6. The integrated circuit of claim 1, wherein a ratio of the load impedance to the reference impedance remains constant over an expected temperature range.

7. The integrated circuit of claim 1, wherein the amplifier further includes a second transistor having third and fourth current-handling terminals coupled in series with a second load, the second transistor exhibiting a second transconductance and the second load a second load impedance that varies with the temperature, and wherein the variable-transconductance-bias circuit is coupled to the second transistor to vary the second transconductance with the temperature.

8. The integrated circuit of claim 7, wherein the second current-handling terminal is connected to the fourth current-handling terminal.

9. The integrated circuit of claim 7, wherein the first and second transistors each have a control terminal, and wherein the control terminals are interconnected.

10. An integrated circuit comprising:
an amplifier having:
a first transistor having first and second current-handling terminals coupled in series with a first load, the first transistor exhibiting a first transconductance and the first load a first load impedance that varies with temperature; and
a second transistor having third and fourth current-handling terminals coupled in series with a second load, the second transistor exhibiting a second transconductance and the second load a second load impedance that varies with the temperature;
a first transconductance-bias circuit coupled to the first transistor, the first transconductance-bias circuit having a first reference element exhibiting a first reference impedance that varies with the temperature and is a linear function of the first load impedance; and
a second transconductance-bias circuit coupled to the second transistor, the second transconductance-bias circuit having a second reference element exhibiting a second reference impedance that varies with the temperature and is a linear function of the second load impedance.

11. The integrated circuit of claim 10, wherein the transconductance-bias circuits vary the transconductance of the respective transistors with changes in the temperature.

12. The integrated circuit of claim 10, wherein the amplifier is a differential amplifier, and wherein the first and second reference impedances are different.

13. The integrated circuit of claim 10, wherein the first and second reference elements include respective control ports to independently control the first and second reference impedances.

14. The integrated circuit of claim 10, wherein the first and second load impedances differ, and wherein the product of the first transconductance and the first load impedance equals the product of the second transconductance and the second load impedance over an operational temperature range.

15. The integrated circuit of claim 10, wherein the first and second load impedances differ, wherein the first and second transconductance bias circuits impose respective first and second bias currents through the respective first and second loads, and the wherein the product of the first bias current and the first load impedance equals the product of the second bias current and the second load impedance over an operational temperature range.

16. The integrated circuit of claim 15, wherein the product of the first transconductance and the first load impedance equals the product of the second transconductance and the second load impedance over the operational temperature range.

17. The integrated circuit of claim 10, wherein the transistors are connected in common-source configurations.

18. The integrated circuit of claim 10, wherein the transistors are connected in a common-gate configuration.

19. A method for controlling an amplifier exhibiting a transconductance and a load impedance that vary with temperature, wherein the amplifier exhibits a gain that is a product of the transconductance and the load impedance, the method comprising:
sensing a temperature change that changes the load impedance;
developing a feedback signal responsive to the temperature change; and
changing the transconductance, responsive to the feedback signal, in inverse proportion to the change in the load impedance.

20. The method of claim 19, wherein the amplifier exhibits a second transconductance and a second load impedance, both of which vary with the temperature, the method further comprising changing the second transconductance responsive to the feedback signal.

21. The method of claim 19, wherein the amplifier exhibits a second transconductance and a second load impedance, both of which vary with the temperature, and wherein the amplifier exhibits a second gain that is a product of the second transconductance and the second load impedance, the method further comprising:
developing a second feedback signal responsive to the temperature change; and
changing the second transconductance, responsive to the second feedback signal, in inverse proportion to the change in the second load impedance.

22. The method of claim 21, wherein the first-mentioned and second load impedances differ, the method further comprising calibrating at least one of the first-mentioned and second transconductances to set the first-mentioned gain equal to the second gain.
